(19) United States
(12) Patent Application Publication
(10) Pub. No.: US 2007/0103965 A1
(43) Pub. Date: May 10, 2007

(54) Memory cell with a vertically integrated delay element

(75) Inventor: Weston Roper, Shakopee, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/268,007

(22) Filed: Nov. 7, 2005

(51) Int. Cl. G11C 11/00

(52) U.S. Cl. 365/154

(57) ABSTRACT

A method and device for a vertically integrated delay element are presented. The vertically integrated delay element includes a portion of an interconnect sandwich. The interconnect sandwich includes dielectric layers and metal layers. The portion of the interconnect sandwich is used to form a capacitor, such as a Metal Insulator Metal (MIM) capacitor, in one or more of the dielectric and metal layers of the interconnect sandwich. The capacitor increases the RC delay time of the delay element. The capacitor is also coupled to a Field Effect Transistor (FET). The FET has an increased drain resistance that may be used to further increase the RC delay of the delay element.

### FIELD

The present invention relates generally to the field of static random access memory cells and more particularly to a static access random memory cell with a vertical delay element for radiation-hardening.

### BACKGROUND

Static Random Access Memory (SRAM) is often used in the cache of a CPU and in digital processing circuits where speed is an important requirement. In contrast to Dynamic Random Access Memory (DRAM), SRAM does not need to be periodically refreshed and it has a faster access time. The access time of SRAM may be an order of magnitude faster than that of DRAM. Additionally, DRAM memory cells, by nature of their design, are more susceptible to radiation events that may easily change the value on a capacitive storage node.

An SRAM includes arrays of individual memory cells. Each memory cell is addressed and accessed so that it may be “read” from or “written” to. Each memory cell also includes a pair of cross-coupled inventers that are used to store either a “high” or “low” voltage level. The cross-coupled inverters are coupled with a pass gate, such as a transistor, that allows the cross-coupled inverters to be read from or written to.

Unfortunately, as circuits scale down to smaller sizes they are more susceptible to single events and soft errors, due largely to reductions in drive currents and voltages which lead to smaller noise margins. Additionally, circuits exposed to radiation environments, such as Space and aerospace, are more susceptible to radiation events. A radiation event, such as a particle strike, may cause a glitch in a circuit node that may cause an SRAM memory cell to change state. A transient glitch in a circuit node is commonly referred to as a Single Event Transient (SET). A glitch or SET that results in a bit-flip or a change in state of a stored value is referred to as a Single Event Upset (SEU).

In contrast to DRAM memory cells, which are typically hardened outside of the memory cell, SRAM memory cells are typically hardened by altering the feedback properties of a memory cell so that an upset occurring at only one node will not propagate through the entire memory cell. One method that is used to prevent radiation events from resulting in an SEU is to introduce a delay element in the signal path of an SRAM memory cell. For example, SRAM memory cell 10, in a six transistor configuration, is illustrated in FIG. 1. Memory cell 10 includes inverter 12 cross-coupled with inverter 14. Inverter 12 includes Field Effect Transistor (FET) 16 coupled with FET 18. Inverter 14 includes FET 20 coupled with FET 22. The coupled drains of FETs 16 and 18 are coupled to a delay 24. The delay 24 is coupled to the gates of FETs 20 and 22.

The memory cell 10, in operation, is written and read by data lines 26 and 28, FETs 30 and 32, and enable input 34. When memory cell 10 is to be read, an enable signal is input to the memory cell at enable (or write) input 34. The enable signal creates a conduction path between the drain and source terminals of FETs 30 and 32. The voltage stored by the cross-coupled inverters at nodes 36 and 38 is then communicated respectively to data lines (or bit lines) 26 and 28.

When the memory cell 10 is to be written to, the enable signal is also communicated to enable input 34. Output drivers, also coupled to signal lines 26 and 28, are used to drive the voltages at nodes 36 and 38. For example, if the voltage at node 36 is low and a high value is to be written, a high voltage is communicated by the output driver to node 36. Node 36 drives the gates of FETs 20 and 22 so that a low voltage is produced at node 38. The low voltage at node 38 is used to drive the gates of FETs 16 and 18 so as to set the voltage at node 36 high. After the memory cell 10 is written, a disable signal may be communicated to enable input 34. The memory cell 10 will store the voltage at nodes 36 and 38 until a read or write operation is to be performed again.

Without delay 24, the memory cell 10 would be more vulnerable to radiation events, such as particle strike. For example, if a glitch (or an SET), induced by a particle strike, occurs on one of the nodes within memory cell 10, it could propagate and cause the memory cell 10 to have an SEU by inverting the voltage stored at nodes 36 and 38. The delay 24, however, prevents the glitch from upsetting the memory cell 10. Basically, the delay 24 will drive a node that has been affected by a glitch back to its correct voltage level before the glitch is propagated through the delay 24. In the example above, if the voltage at node 38 is low, a glitch may cause the voltage at node 38 to go high. This high voltage will drive node 36 low. Delay 24, however, will continue to drive the gates of FETs 20 and 22 high so that node 38 returns low.

Delay 24 creates an RC delay which effectively delays the switching, or response time of the cross-coupled inverters. If the response time is greater than the recovery time (i.e., the recovery time associated with a glitch from a radiation event), the memory cell 10 may be viewed as radiation-hardened. Radiation-hardening allows a memory cell to achieve SEU and soft error immunity from radiation events.

In order to create the RC delay, delay 24 may use a resistor-capacitor pair 40 and 42, as illustrated in FIG. 1b. The resistor 40 and capacitor 42 combine with any interconnect resistances and parasitic capacitances to provide a propagation signal delay that is proportional to the product of their respective resistance and capacitance. In other radiation-hardened designs, active components such as diodes and transistors may be used in place of these passive elements to more appropriately increase the delay. However, the addition of multiple passive and active device components may generally cause the size of the standard SRAM cell to increase, resulting in lower manufacturing yields and higher production costs. For example, as illustrated in FIG. 1c, inverters 12 and 14 and FETs 30 and 32 may take up an area of 6.875 μm² (2.5 μm×2.75 μm). The delay 24 may take up an area of 3.125 μm² (2.5 μm×1.25 μm). In this example, 30% of the area of the memory cell is taken up by the delay 24.

Therefore, it would be desirable to design an SRAM memory cell that is protected against single event and soft error phenomena and that also requires a smaller memory cell area.

### SUMMARY

A Static Random Access Memory (SRAM) cell with a vertically integrated delay element is presented. The delay element is used to create an RC delay between a pair of cross-coupled inverters. The memory cell includes an interconnect sandwich located on top of a device sandwich. The active devices, including the pair of cross-coupled inverters, are fabricated in the device sandwich. The large-area passive elements of the delay are fabricated in the interconnect sandwich. One of the large-area passive elements includes a capacitor formed out of one or more metal and dielectric layers located in the interconnect sandwich. The capacitor may be a Metal Insulator Metal (MIM) type capacitor or a ferroelectric type. Another passive element that may be included in the interconnect sandwich is a thin film resistor, which is also formed out of one or more of the metal layers located in the interconnect sandwich.

Other examples include adjusting the RC delay by decreasing the drain-drain resistance value of one of the cross-coupled inverters. Additionally, the drive strength and switching points of the cross-coupled inverters may also be adjusted to tailor the RC delay.

These as well as other aspects and advantages will become apparent to those of ordinary skill in the art by reading the following detailed description, with reference where appropriate to the accompanying drawings. Further, it is understood that this summary is merely an example and is not intended to limit the scope of the claims.

### BRIEF DESCRIPTION OF THE DRAWINGS

Certain examples are described below in conjunction with the appended drawing figures, wherein like reference numerals refer to like elements in the various figures, and wherein:

FIG. 1a is a circuit diagram of a radiation-hardened Static Random Access Memory (SRAM) cell;

FIG. 1b is a circuit diagram of a delay element;

FIG. 1c is a block diagram of the area associated with circuit components of an SRAM cell;

FIG. 2a is another circuit diagram of an SRAM cell;

FIG. 2b is a block diagram of the area associated with circuit components of an SRAM cell including a vertically integrated delay element;

FIG. 2c is a cross-sectional diagram of a Field Effect Transistor (FET) coupled to a vertically integrated delay element;

FIG. 3a is another circuit diagram of an SRAM cell;

FIG. 3b is another cross-sectional diagram of a FET coupled to a vertically integrated delay element;

FIG. 4a is another circuit diagram of an SRAM cell;

FIG. 4b is another cross-sectional diagram of a FET coupled to a vertically integrated delay element; and

FIG. 5 is a flow diagram of a method for fabricating an SRAM with a vertically integrated delay element.

### DETAILED DESCRIPTION

An apparatus and method for integrating a passive delay element into an SRAM cell are presented. The delay element may be used to radiation-harden the memory cell. Additionally, a passive component of the delay element is located above an active device so that the overall area of the memory cell may be reduced. The delay element includes a capacitor located in an interconnect sandwich. This capacitor may be a Metal Insulator Metal (MIM) type capacitor. Alternatively, the capacitor may be a ferroelectric type capacitor. The RC delay associated with the delay element may be adjusted by increasing the resistance of the drain-drain coupling of one of the active devices. Additionally, a thin film resistor, located in the interconnect sandwich, may also be coupled with the capacitor. The RC delay may be further adjusted by decreasing the drive strength of one of the inverters and centering the switching point of the cross-coupled inverters.

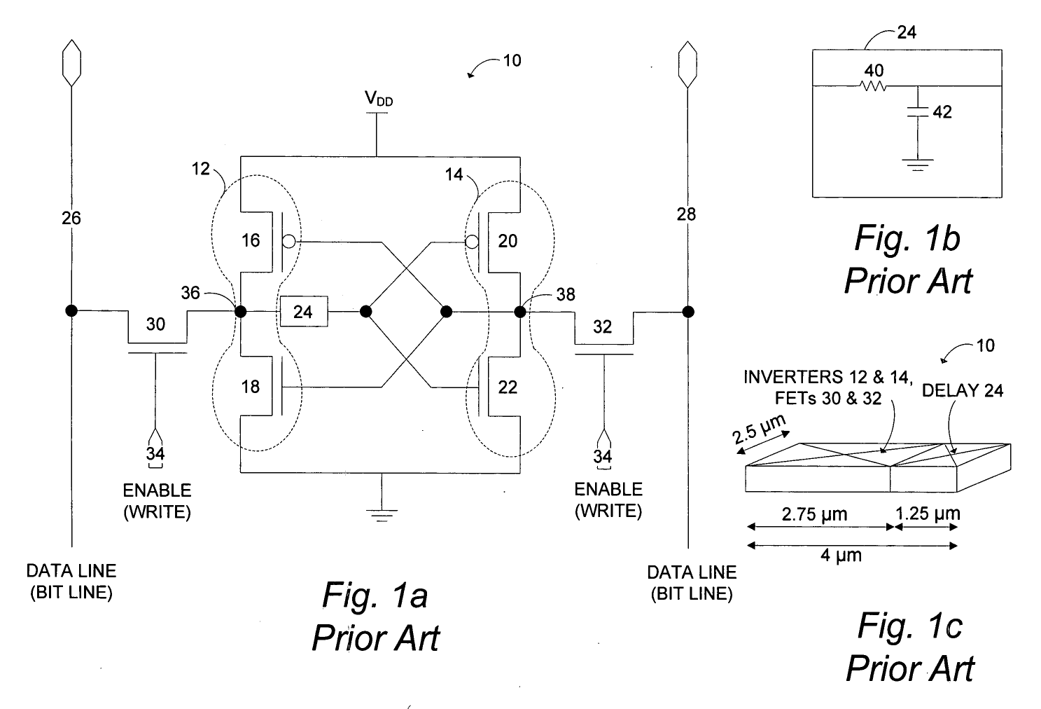

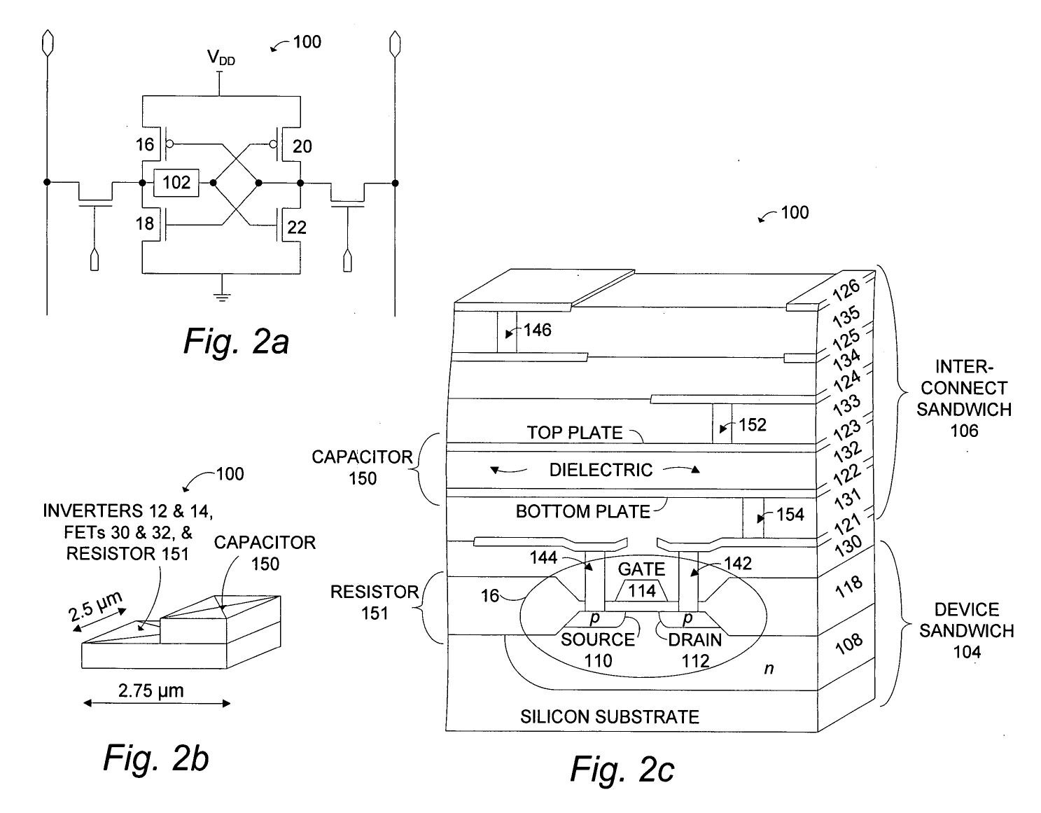

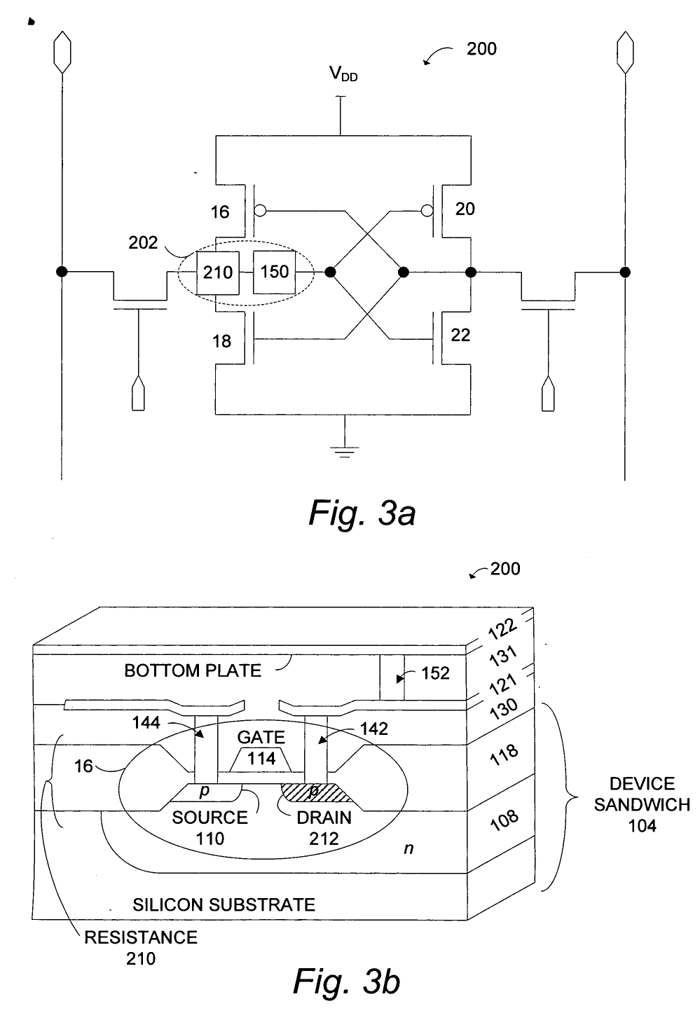

Turning now to FIG. 2a, memory cell 100 is presented in FIG. 2. The memory cell 100 contains most of the elements of memory cell 10; however, delay 24 is replaced with a vertically integrated delay component 102. The vertically integrated delay component 102 may be used to radiation-harden the memory cell 100. Because devices such as capacitors and diodes may take up a large percentage of a memory cell's area, some of the passive components of the delay 102 may not be located in the device layer of the memory cell 100. Instead, large-area passive components may be located in the interconnect layer of the memory cell 100. For example, in FIG. 2b, a capacitor 150, which is a passive components of delay 102, may be located above inverters 12 and 14 and FETs 30 and 32. The overall area (6.875 μm²) of the memory cell 100 is reduced by over 30% in comparison to the overall area (10 μm²) of the memory cell 10 in FIG. 1c. A small-area passive component, such as resistor 151, may be included in the device layer of memory cell 100. Incorporation of a resistor or resistance will be further described with reference to FIGS. 2c, 3a, and 3b.

FIG. 2c illustrates the device layer (device sandwich) 104, and the interconnect layer (interconnect sandwich) 106. The interconnect sandwich 106 is located on top of the dielectric sandwich 104. The interconnect sandwich 106 includes the metallization layers, dielectric layers, and vias that are used to couple transistors and other devices located in or used by the memory cell 100. The device sandwich 104, on the other hand, includes the FETs used to construct the inverters 12, 14 of memory cell 100. A cross-sectional view of FET 16 is also shown in FIG. 2c. FET 16 includes an n-type well 108, a source 110, formed in a p-type region, a drain 112, also formed in a p-type region, and a gate 114. FET 16 may be isolated from other FETs by a dielectric isolating layer 118.

The interconnect sandwich 106 includes all of the layers located above a dielectric layer 130, including the dielectric layer 130. The device sandwich 104 includes all of the layers located below dielectric layer 130. The other layers included in the interconnect sandwich 106 are metal layers 121-126 and dielectric layers 131-135.

The interconnect sandwich 106 is isolated from the device sandwich 104 by the dielectric layer 130. The interconnect sandwich 106 is used to couple devices within the device sandwich 104 to other devices. The interconnect sandwich 106 also provides electrical coupling to other devices external to an integrated circuit package. The device sandwich 104 is coupled to the interconnect sandwich 106 by contacts, such as contact 142 and 144. The contacts 142 and 144 provide electrical coupling through dielectric layer 130 to the respective source 110 and drain 112 of FET 16. Metal layer 121 may be patterned so as to route the electrical couplings of the source 110 and drain 112 to other devices located within the device sandwich 104. Additional routing may be carried out with metal layers 122-126. Metal layers 121-126 may be intercoupled by vias. One such via, via 146, is used to intercouple a patterned portion of metal layer 125 to a patterned portion of metal layer 126.

As illustrated in FIG. 2c, many metal and dielectric layers may be used to interconnect devices within the device sandwich 104. The interconnect sandwich 106 may also be used to create devices. One such device, as described above, is capacitor 150. Capacitor 150 is formed in metal layers 122 and 123 and dielectric 132. Capacitor 150 may also be referred to as a Metal Insulator Metal (MIM) capacitor.

To create capacitor 150, metal layer 122 may be patterned to form a bottom plate of capacitor 150. Likewise, metal layer 123 may be patterned to form a top plate of capacitor 150. The patterning of the top and bottom plates may be tailored to create a plate area. The plate area is used to determine the capacitance value of the RC delay of delay 102. Additionally, the dielectric layer 132 thickness and/or dielectric constant of the dielectric layer may be optimized for a desired capacitance value. The dielectric thickness may also be increased by using more than one dielectric layer. For example, patterned portions of metal layers 124 and 122 could be used as respective top plates and bottom plates. Both dielectric layers 132 and 133 could then be used as the dielectric of a capacitor. Alternatively, capacitor 150 may also be located in a different strata of the interconnect sandwich 106. Capacitor 150 may be formed in metal layers 124 and 125 and dielectric layer 134, for example.

Capacitor 150's top plate or bottom plate may be directly coupled to other devices or voltages (such as a common voltage) by way of vias 152 and 154. In FIG. 2c, a bottom plate coupling is shown. The drain 112 of FET 16 is coupled to a patterned portion of metal layer 121 by way of contact 142. The patterned portion of metal layer 121 is coupled to the bottom plate of capacitor 150 by via 152. Via 154, may be used to couple the top plate of capacitor 150 to another device or a common voltage.

The metal layers, dielectric layers, contact, and vias may all be formed in conventional Complementary Metal Oxide Semiconductor (CMOS) processes. More or fewer metal and dielectric layers may be included. The contacts and vias may be tungsten, for example. The metal layers may be aluminum or copper. The metal layers may also include titanium or titanium nitride to couple the vias and contacts to the metal layers. The contacts may be coupled to a device in the device sandwich 104 by a conventional salicide process, such as a silicided region of source 110 and drain 112.

The devices formed in the device sandwich 104 may be those that are formed in general CMOS processing. The substrate of the device sandwich 104 may be a bulk silicon type or Silicon-On-Insulator (SOI). The gate 114, for example, may include polysilicon deposited on top of a thin silicon dioxide layer. In other examples, the source 110 and drain 112 may be n-type or p-type. Additionally the well 108 may also be n-type or p-type. The RC delay of a memory cell may be further determined by modifying inverters 12 and 14. For example, the resistance value of the drains of FETs 16 and/or 18 may be increased. Resistor 151 may be formed in FET 16. This may be done by increasing the resistance per unit length of drain 112. The length of drain 112 (relative to the source 114) may then be increased to increase the overall resistance of FET 16. In the above configurations, inverter 12 may be viewed as “master” and inverter 14 may be viewed as a “slave”. Inverter 14 may also be modified. The resistance and capacitance of FETs 20 and 22 may be increased to further determine an RC delay, for example.

In FIG. 3a, a memory cell 200 with delay 202 is illustrated. Delay 202 includes capacitor 150 coupled with resistance 210. As described above, the resistance 210 may be formed in the drain of FET 16. Alternatively the resistance 210 may include a thin film metal resistor in the interconnect sandwich 104.

FIG. 3b illustrates an example of increasing the drain resistance of FET 16. The cross-section of FET 16 shows the resistance of the drain of FET 16 being increased by forming a lightly doped drain 212. The lightly doped drain 212 may have a lighter doping density than other FETs used in the memory cell 200 (e.g., FETs 20 and 22). The lightly doped drain 212 may be created by conventional implanting techniques. This lighter doping may increase the “ohmic” contact to the drain 212.

Another type of a resistance that may be coupled to capacitor 150, as mentioned above, is a thin film metal resistor. A thin film resistor may also improve area optimization of a memory cell by being incorporated in the interconnect sandwich 104. A metal layer, such as any one of metal layers 121-126, may be used to create a resistance. A metal layer may be thinned or etched to increase the resistance of a signal path through the metal layer. Alternatively, a thin metal layer may be deposited in the interconnect sandwich 104. The thin metal layer may then be patterned to create a desired resistance. A via or contact may be used to couple a device to the patterned-thin metal resistance. Additionally, the thin metal resistance may be coupled with a drain resistance and/or a conventional polysilicon resistor to further determine the resistance associated with the RC delay of the delay 202.

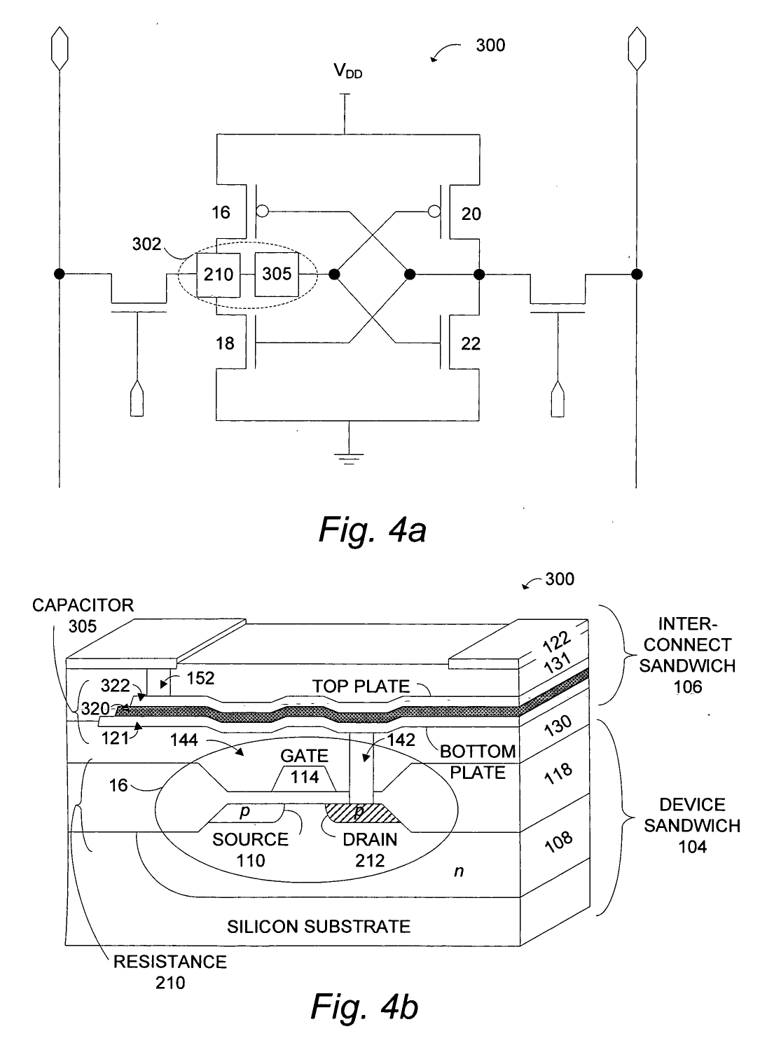

As described above, capacitor 150 may be a MIM capacitor. Alternatively, other types of capacitor may be formed in the interconnect sandwich 104. In FIG. 4a, another type of capacitor used to create delay 302 in memory cell 300 is ferroelectric capacitor 305. Resistance 210 is also coupled with capacitor 305.

Due to their generally high dielectric constants and large resistance, ferroelectric materials are ideally suited as dielectric layers in capacitors. The high dielectric constant of ferroelectric materials results in capacitors of a given capacitance requiring a smaller overall area than those utilizing general oxide dielectrics. The dielectric material used in a ferroelectric capacitor may be lead zirconium titanate (PbZrₓ Ti₁₋ₓO₃), strontium bismuth tantalite (SrBi₂Ta₂O₉), bismuth lanthanum titanate (Bi₄₋ₓ Laₓ TiO₁₂),any other type of ferroelectric material.

A cross section of capacitor 305 is illustrated in FIG. 4b. A ferroelectric dielectric layer 320 forms the dielectric of capacitor 305. The top plate of the capacitor 305 may be patterned from metal layer 322. Metal layer 322 may be deposited directly on top of the ferroelectric dielectric layer 320. The bottom plate of capacitor 305 may be a patterned portion of metal layer 121. FET 16 is coupled to the bottom plate of capacitor 305 by contact 142. Via 330 may be used to couple capacitor 305 to a common voltage, external circuitry, or other devices within the device sandwich 104.

In other examples, capacitor 305 may be located in a different strata of the interconnect sandwich 106. For example, capacitor 305 could be located in between the metal layers 124 and 125 of FIG. 2c. Additionally, capacitor 305 may be used by itself or with other capacitors, such as capacitor 150, to determine the capacitance of the RC delay of delay 302. Similar to the examples of FIG. 3a and 3b, capacitor 305 may also be coupled with a drain resistance formed in FET 16 or FET 18 and/or a thin film resistor formed in a different strata of interconnect sandwich 106.

Other methods of increasing the RC delay include increasing the gate oxide thickness of FETs 16 and 18 in relation to the gate oxide thickness of FETs 20 and 22. This reduces the drive strength of FETs 16 and 18 in relation to FETs 20 and 22. Reducing the drive strength will further increase the RC delay of delays 102, 202, or 302. Additionally, centering the switching point of inverter 14 may also increase the RC delay. By adjusting the turn-on voltage of FETs 20 and 22 to a voltage that is centered between the power supply and common voltage supplied to memory cells 100, 200, or 300, the RC delay associated with delay 102, 202, or 302 will be maximized.

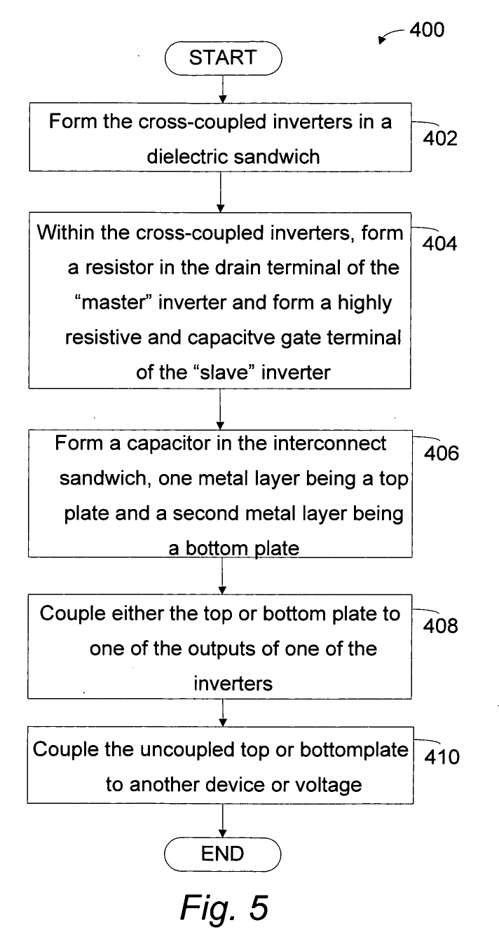

Overall, the above examples describe a method and apparatus of vertically integrating a delay element into a memory cell. The method, as shown in the flow diagram of FIG. 5, includes increasing the resistance and/or capacitance of master and slave inverters, as shown at block 404. It also includes forming a capacitor in the interconnect sandwich of a memory cell, as shown at block 406. The inverters are coupled to a top or bottom plate of the capacitor, as shown at block 408. The other plate of the capacitor may be. coupled to another device or voltage (such as a common voltage), as shown at block 410.

The capacitance of the RC delay of the delay element is determined by the capacitance of the capacitor and the resistance and capacitance of other passive devices located in the interconnect sandwich. The properties of the devices in the device sandwich 104 may also be altered to adjust the RC delay of the delay element. A variety of the above methods may be used to optimize a vertically integrated delay element. The optimization of the delay element may be used to radiation-harden a particular memory cell for a particular radiation environment.

It should be understood that the illustrated examples are examples only and should not be taken as limiting the scope of the present invention. The claims should not be read as limited to the described order or elements unless stated to that effect. Therefore, all examples that come within the scope and spirit of the following claims and equivalents thereto are claimed as the invention.

I claim:

1. A memory cell, comprising:
a device sandwich formed on a substrate;
an interconnect sandwich formed on top of the device sandwich, the interconnect sandwich including first and second metal layers and a dielectric layer located in between the first and second metal layers;
a pair of cross-coupled inverters located in the device sandwich; and
a capacitor formed in a portion of the first and second metal layers and the dielectric layer, the portion of the first metal layer being a bottom plate of the capacitor, the portion of the second metal layer being a top plate of the capacitor, and the pair of cross-coupled inverters coupled with the capacitor so as to create a delay in signal transmission between the pair of cross-coupled inverters.

2. The method as in claim 1, wherein an output of one of the inverters of the pair of cross-coupled inverters has a resistance formed in the output, thereby further increasing the delay in signal transmission.

3. The method as in claim 2, wherein the resistance is a drain resistance of a Field Effect Transistor (FET), the pair of cross-coupled inverters comprising the FET.

4. The memory cell as in claim 2, wherein the capacitor is a Metal Insulator Metal (MIM) type capacitor and the dielectric layer is a silicon dioxide (SiO₂) layer.

5. The memory cell as in claim 2, wherein the capacitor is a ferroelectric capacitor and the dielectric layer is a ferroelectric material.

6. A method of fabricating a memory cell, the method comprising:
forming a dielectric sandwich on a substrate, the dielectric sandwich including at least a first inverter and a second inverter, the first and second inverters being cross-coupled and having respective inputs and outputs; and
forming an interconnect sandwich on top of the dielectric sandwich, the interconnect sandwich coupled to the dielectric sandwich and including first and second metal layers and a first dielectric layer located in between the first and second metal layers, wherein forming the interconnect sandwich includes:
forming a first capacitor in the interconnect layer, a bottom plate of the first capacitor being a portion of the first metal layer, a dielectric of the capacitor being a portion of the first dielectric layer, and a top plate of the first capacitor being a portion of the second metal layer; and
coupling one of the plates of the first capacitor to the output of the first inverter; and
coupling the other plate of the first capacitor to a common voltage, thereby creating a delay in signal transmission between the output of the first inverter and the input of the second inverter.

7. The method of claim 6, further comprising forming a resistance in a drain-drain coupling of a p-type Field Effect Transistor (pFET) and an n-type Field Effect Transistor (nFET), the first inverter comprising the pFET and nFET, and the resistance further increasing the delay in signal transmission.

8. The method as in claim 6, wherein the first capacitor is a Metal Insulator Metal (MIM) capacitor, the dielectric being silicon dioxide (SiO₂).

9. The method as in claim 6, wherein the first capacitor is a ferroelectric capacitor and the dielectric is a ferroelectric material.

10. The method as in claim 6, further comprising coupling the output of the first inverter to a thin film metal resistor located in a third metal layer, the interconnect sandwich comprising the third metal layer, and the thin film metal resistor further increasing the delay in signal transmission.

11. The method as in claim 6, furthering comprising forming a second capacitor in the interconnect layer, the interconnect layer further including third and fourth metal layers and a second dielectric layer located in between the third and fourth metal layers, a bottom plate of the second capacitor being a portion of the third metal layer, a top plate of the second capacitor being a portion of the fourth metal layer, a dielectric of the second capacitor being a portion of the second dielectric layer and the second capacitor further increasing the delay in signal transmission.

12. A memory cell, comprising:
a device sandwich;
an interconnect sandwich being located on top of the device sandwich, the interconnect sandwich including first and second metal layers and a dielectric layer, the dielectric layer located in between the first and second metal layers;
first and second p-type Field Effect Transistors (pFETs) each having a gate, a source, and a drain, the first and second pFETs located in the device sandwich;
first and second n-type Field Effect Transistors (nFETs) each having a gate, a source and a drain, the first and second nFETs located in the device sandwich, and the drains of the second nFET and pFET coupled to the gates of the first nFET and pFET; and
a capacitor formed in a portion of the first and second metal layers and the dielectric layer, the portion of the first metal layer being a bottom plate of the capacitor, the portion of the second metal layer being a top plate of the capacitor, the drains of the first pFET and nFET being coupled to the gates of the second pFET and nFET, and the drains of the first pFET and nFET being coupled to one of the plates of the capacitor.

13. The memory cell as in claim 12, wherein the capacitance value associated with the capacitor increases a signal propagation time between the drains of the first pFET and nFET and the gates of the of the second pFET and nFET.

14. The memory cell as in claim 13, wherein the capacitor is a Metal Insulator Metal (MIM) type capacitor and the dielectric layer is a silicon dioxide (SiO₂) layer.

15. The memory cell as in claim 13, wherein the capacitor is a ferroelectric capacitor and the dielectric layer is a ferroelectric material.

16. The memory cell as in claim 13, wherein a resistance value associated with the drain of the first nFET is larger than a resistance value associated with the drain of the second nFET thereby further increasing the signal propagation time.

17. The memory cell as in claim 13, wherein a resistance value associated with the drain of the first pFET is larger than a resistance value associated with the drain of the second pFET thereby further increasing the signal propagation time.

18. The memory cell as in claim 17, wherein a resistance value associated with the drain of the first nFET is larger than a resistance value associated with the drain of the second nFET thereby further increasing the signal propagation time.

19. The memory cell as in claim 18, wherein the gates of the first nFET and pFET are thicker than the gates of second nFET and pFET, the thicker gates of the first nFET and pFET reducing the drive strength of the first nFET and PFET thereby further increasing the signal propagation time.

20. The memory cell as in claim 19, wherein the second nFET and pFET each have a turn on voltage that is at a voltage level halfway between a power supply voltage and a common voltage supplied to the memory cell, thereby further increasing the signal propagation time.
